(19) United States
(12) Patent Application Publication
(10) Pub. No.: US 2023/0153587 A1
(43) Pub. Date: May 18, 2023

(54) Stacked-Die Neural Network with Integrated High-Bandwidth Memory

(71) Applicant: Rambus Inc., San Jose, CA (US)

(72) Inventors: Thomas Vogelsang, Mountain View, CA (US); Steven Woo, Saratoga, CA (US); Liji Gopalakrishnan, Sunnyvale, CA (US)

(21) Appl. No.: 17/910,739

(22) PCT Filed: Mar. 23, 2021
(86) PCT No.: PCT/US2021/023608

§ 371 Date: Sep. 9, 2022

Related U.S. Application Data
(60) Provisional application No. 63/001,859, filed on Mar. 30, 2020.

(51) Int. Cl. G06N 3/063; H10B 80/00; G06N 3/084

(52) U.S. Cl. CPC G06N 3/063; G06N 3/084; H10B 80/00

(57) ABSTRACT

A neural-network accelerator die is stacked on and integrated with a high-bandwidth memory so that the stack behaves as a single, three-dimensional (3-D) integrated circuit. The accelerator die includes a high-bandwidth memory (HBM) interface that allows a host processor to store training data and retrieve inference-model and output data from memory. The accelerator die additionally includes accelerator tiles with a direct, inter-die memory interfaces to a stack of underlying memory banks. The 3-D IC thus supports both HBM memory channels optimized for external access and accelerator-specific memory channels optimized for training and inference.

### BACKGROUND

Artificial neural networks are computing systems inspired by biological neural networks (e.g., brains). Artificial neural networks (hereafter just “neural networks”) include interconnected collections of artificial neurons that loosely model their biological counterparts. Neural networks “learn” to perform tasks by the repetitious consideration of examples. We know, for example, that for some varieties of fruit human observers can learn to visually distinguish ripe from unripe samples. We may not know precisely what visual information the expert sorter relies upon, though we can guess that ripeness correlates to some function of the texture, size, and color evident in images of sample fruit. A neural network can derive that “ripeness” function of image data. That function can then be used to “infer” sample ripeness from images of unsorted fruit.

“Supervised learning” is one approach to training neural networks. In the fruit-sorting example, a neural network is provided with images that have been manually labeled by a human taster as depicting “ripe” or “unripe” fruit. The untrained neural network starts with a default sorting function, or “model,” that likely bears little resemblance to an optimized one. Images applied to the untrained neural network thus produce large errors between inferred and labeled ripeness. Using a learning process called “back propagation,” the neural network adjusts weights applied by its constituent neurons in a way that tends to reduce the errors responsive to sets of training data. The predictive model thus becomes more reliable with training.

Neural networks are tasked with solving problems much more complex than sorting fruit. For example, neural networks are being adapted for self-driving vehicles, natural-language processing, and a host of biomedical applications like diagnostic image analysis and drug design. Neural networks charged with addressing these difficult classes of problems can be fantastically complex. Training thus requires vast amounts of training data, and myriad neurons require fast access to storage for values computed during the training process, as well as those settled upon in training and used for inference. Complex neural networks thus require fast, efficient access to large amounts of high-performance memory.

### BRIEF DESCRIPTION OF THE DRAWINGS

The present disclosure is illustrated by way of example, and not by way of limitation, in the figures of the accompanying drawings. For elements with numerical designations the first digit indicates the figure in which the element is introduced, and like references refer to similar elements within and between figures.

FIG. 1 depicts an information processing device 100, a three-dimensional (3-D) application-specific integrated circuit (ASIC) in which a processor die, in this case a neural-network accelerator die 105, is bonded to and electrically interconnected with a stack of four dynamic, random-access memory (DRAM) die 110 using e.g. through-silicon vias (TSVs) or Cu-Cu connections so that the stack behaves as a single IC device.

FIG. 2 is a plan view of an embodiment of device 100 of FIG. 1 in which accelerator die 105 includes eight sets of four tiles (e.g. sets ACC[7:4] and ACC[3:0]), four of which sets are shown, and each underlying DRAM die includes eight sets 200 of eight banks B[7:0].

FIG. 3 is a block diagram of a portion of accelerator die 105 of FIGS. 1 and 2, including external interface HBM0 and accelerator tiles ACC0 and ACC3.

FIG. 4A is a block diagram of a 3-D ASIC 400 in accordance with an embodiment that includes an accelerator die 405 and a pair of DRAM dies DD0 and DD1.

FIG. 4B reproduces block diagram 400 of FIG. 4A but with direct-channel blocks DCA and DCB and related signal lines highlighted using bold lines to illustrate signal flow in an internal-access mode in which accelerator tiles (not shown) on accelerator die 405 access DRAM dies DD0 and DD1 directly.

FIG. 5 depicts a 3-D ASIC 500 in accordance with another embodiment. ASIC 500 is similar to device 100 of FIG. 1, with like-identified elements being the same or similar.

FIG. 6A depicts a computer system 600 in which a system-on-a-chip (SOC) 605 with host processor 610 has access to a 3-D processing device 100 of the type detailed previously.

FIG. 6B depicts system 600 in an embodiment in which SOC 605 communicates with device 100 via an interposer 640 with finely spaced traces 645 etched in silicon.

FIG. 7A depicts an address field 700 that can be issued by a host processor to load a register in accelerator die 105 to control the mode.

FIG. 7B depicts an address field 705 that can be used by a host processor for aperture-style mode selection.

FIG. 7C depicts two address fields, an external-mode address field 710 that can be issued by a host processor to access a page of DRAM in the HBM mode and an internal-mode address field 715 that can be used by an internal memory controller for similar access.

FIG. 8 illustrates an application-specific integrated circuit (ASIC) 800 for an artificial neural network with an architecture that minimizes connection distances between processing elements and memory (e.g. stacked memory dies), and thus improves efficiency and performance.

FIG. 9 illustrates four accelerator tiles 820 interconnected to support concurrent forward and back propagation.

FIG. 10 includes a functional representation 1000 and an array 1005 of a neural network instantiated on a single accelerator tile 820.

FIG. 11A depicts a processing element 1100, an example of circuitry suitable for use as each processing element 1020 of FIG. 10.

FIG. 11B depicts processing element 1100 of FIG. 11A with circuit elements provided in support of back propagation highlighted using bold line widths.

FIG. 13 illustrates information flow during back propagation through accelerator tile 1200 of FIG. 12.

### DETAILED DESCRIPTION

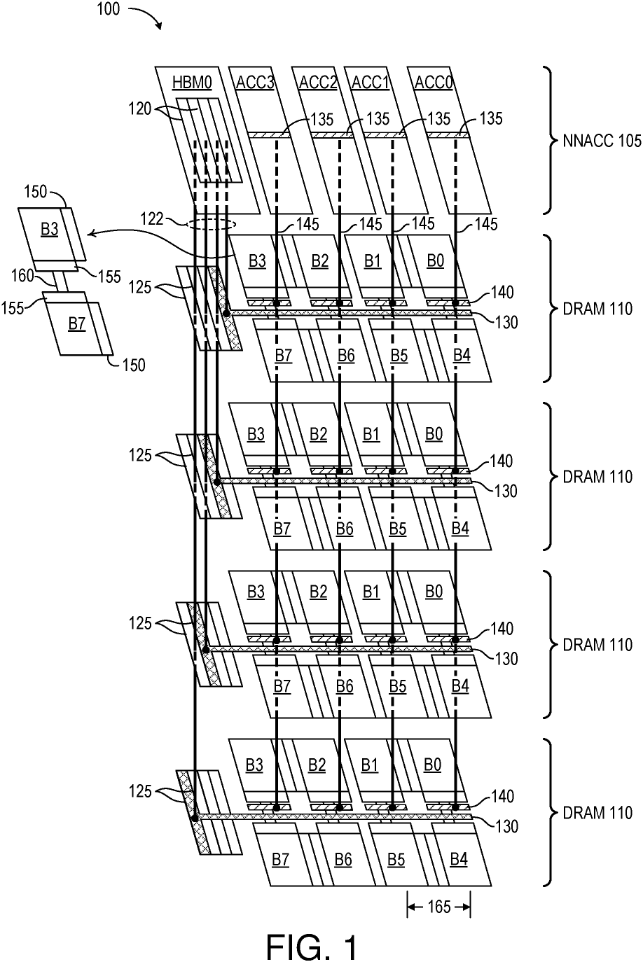

FIG. 1 depicts an information processing device 100, a three-dimensional (3-D) application-specific integrated circuit (ASIC) in which a processor die, in this case a neural-network accelerator die 105, is bonded to and electrically interconnected with a stack of four dynamic, random-access memory (DRAM) die 110 using e.g. through-silicon vias (TSVs) or Cu-Cu connections so that the stack behaves as a single IC device. Accelerator die 105 includes a high-bandwidth memory (HBM) interface HBM0 divided into four HBM sub-interfaces 120. Each sub-interface 120 includes a via field (an area encompassing TSVs) providing connections 122 to a horizontal memory-die data port 125 that extends to eight memory banks B[7:0] on one of DRAM dies 110 by way of horizontal (intra-die) connections 130. The horizontal memory-die data port 125 and respective connection 130 are shaded on each DRAM die 110 to highlight the signal paths for intra-die access to a set of eight memory banks B[7:0] on the respective DRAM die 110, each bank being an independently addressable array of data storage elements. Interface HBM0 allows a host processor (not shown) to store training data and retrieve inference-model and output data from DRAM dies 110. Accelerator die 105 also includes four processing tiles, neural-network accelerator tiles ACC[3:0], each including a via field 135 to a vertical (inter-die) memory-die data port 140 on each of the underlying DRAM dies 110. Tiles ACC[3:0] and underlying memory banks B[7:0] are laid out to establish relatively short inter-die connections 145. Stacks of banks (e.g. the four bank pairs B[4,0]) thus form vertical collections of high-bandwidth memory in service of accelerator tiles 130. Device 100 thus supports both DRAM-specific HBM memory channels optimized for external access and accelerator-specific memory channels optimized to support accesses for training and inference.

HBM DRAM supports bank grouping, a method which doubles the data rate on the external interface compared to the data rate of one bank by interleaving bursts from banks belonging to different bank groups. DRAM dies 110 are, in this embodiment, modified to support relatively direct, inter-die connections to accelerator tiles ACC[3:0]. The eight banks B [7:0] in each DRAM die 110 represent one set of banks connected to horizontal memory-die data port 125. In this embodiment, bank grouping is implemented by interleaving bursts from B[3:0] with bursts from facing banks B[7:4]. As shown at left in FIG. 1 for a pair of DRAM banks B[7,3], each bank includes a row decoder 150 and a column decoder 155. Links 160 communicate read and write data at the DRAM core frequency. Each set of banks includes four inter-die data ports 140, one for each pair of memory banks directly under one of accelerator tiles ACC[3:0]. In the rightmost instance, for example, vertical, inter-die connections 145 connect accelerator tile ACC0 to an inter-die data port 140 serving bank pair B [4,0] in each of the four underlying DRAM dies 110 in the die stack. Tile ACC0 thus has rapid, energy-efficient access to eight underlying memory banks. In other embodiments, the number of vertically accessible memory banks does not equal the number of memory banks in a set of banks.

The intra-die (horizontal) and inter-die (vertical) connections can include active components (e.g. buffers), and the intra-die signal paths can include inter-die segments, and vice versa. As used herein, a connection to a memory bank is “intra-die” if it has an intra-die segment that extends along the plane of a DRAM die over a distance greater than the shortest center-to-center spacing of the DRAM banks on the die (i.e. greater than the memory-bank pitch 165). A connection to a memory bank is “inter-die” if it extends from one die to the closest DRAM bank in another die using an intra-die segment or segments, if any, of a length less than bank pitch 165.

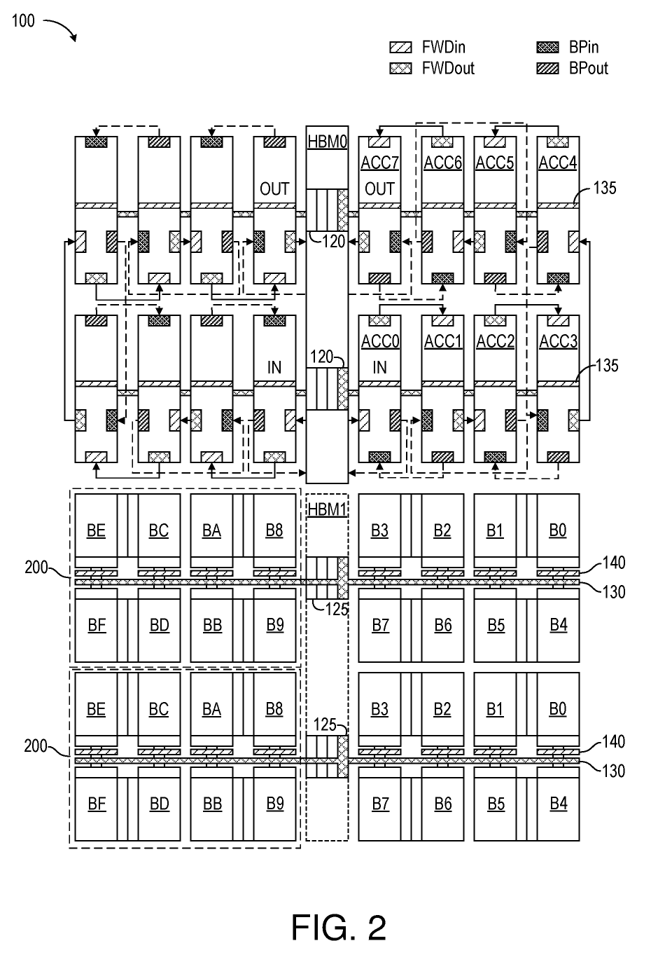

FIG. 2 is a plan view of an embodiment of device 100 of FIG. 1 in which accelerator die 105 includes eight sets of four tiles (e.g. sets ACC[7:4] and ACC[3:0]), four of which sets are shown, and each underlying DRAM die includes eight sets 200 of eight banks B[7:0]. Half of the accelerator tiles are omitted to show four of the eight bank sets 200 in the uppermost DRAM die 110; a dashed boundary labeled HBM1 shows the location of the HBM interface of the obscured portion of the accelerator die. The via fields of sub-interfaces 120 and underlying ports 125 are located in center stripes of the accelerator and DRAM dies and are separated by die position in the stack so that each pair of sub-interfaces 120 communicates with only one of the underlying DRAM dies. Sub-interface (pseudo-channel) connectivity is highlighted by shading for the uppermost DRAM die; the remaining three DRAM dies are obscured.

Accelerator die 105 is bonded to and electrically interconnected with a stack of four DRAM die 110 in this embodiment, each DRAM die supporting two memory channels for an external host (not shown). Each external channel includes two pseudo channels that share command and address infrastructure and communicate data via respective sub-interfaces 120. Each of the shaded pair of sub-interfaces 120 of interface HBM0 represents a pseudo-channel port, and the pair a channel port, in this example. Each pseudo channel, in turn, provides access to two sets of banks SB via a pair of intra-die connections 130 that extend from the respective sub-interface 120. Two of sub-interfaces 120 are shaded to match corresponding infra-die connections 130 in the uppermost DRAM die to highlight the flow of data along two of the four pseudo channels. Each of the remaining three external channels is likewise served via one of the three underlying but obscured DRAM dies. Device 100 includes more or fewer DRAM dies in other embodiments.

Accelerator tiles ACC# can be described as “upstream” or “downstream” with respect to one another and with reference to signal flow in the direction of inference. For example, tile ACC0 is upstream from tile ACC1, the next tile to the right. For inference, or “forward propagation,” information moves along the unbroken arrows through the chain of tiles, emerging from the ultimate downstream tile ACC7. For training, or “back propagation,” information moves along the broken arrows from the ultimate downstream tile ACC7 toward the ultimate upstream tile ACC0. In this context, a “tile” is a collection of processing elements arranged in a rectangular array. Accelerator tiles can be placed and interconnected to allow efficient inter-tile communication. Processing elements within a tile can operate as a systolic array, as detailed below, in which case tiles can be “chained” together to form larger systolic arrays.

Each accelerator tile ACC# includes four accelerator ports, two each for forward propagation and back propagation. A key at the upper right of FIG. 2 shows shading that identifies in each tile 120 a forward-propagation input port (FWDin), forward-propagation output port (FWDout), back-propagation input port (BPin), and back-propagation output port (BPout). (This key does not apply to other shaded elements in FIG. 2.) Tiles ACC# are oriented to minimize connection distances and concomitant propagation delays. In some embodiments, each accelerator tile includes processing elements that can concurrently process and update partial results from both upstream and downstream processing elements and tiles in support of concurrent forward and back propagation.

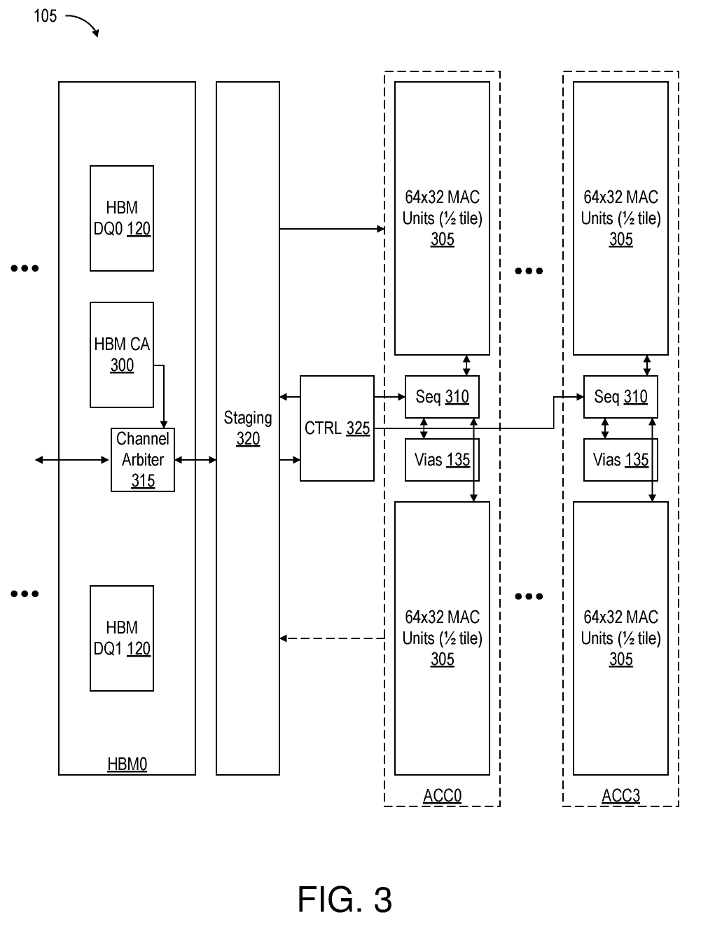

FIG. 3 is a block diagram of a portion of accelerator die 105 of FIGS. 1 and 2, including external interface HBM0 and accelerator tiles ACC0 and ACC3. Die 105 communicates externally using an external channel interface comprising a pair of sub-interfaces 120, detailed previously, and a command/address (CA) interface 300. Each accelerator tile ACC# includes two half-tiles 305, each with a 64x32 array of multiply-accumulators (MACs or MAC units), each of which computes the product of two numbers and adds that product to an accumulating value. (Suitable MACs are detailed below.) A memory controller 310 in each tile manages DRAM access along the inter-die channels associated with via fields 135. Controllers 310 are labeled “seq” for “sequencer,” which refers to a simple and efficient class of controller that generates sequences of addresses to step though a microprogram. In this embodiment, the MAC units perform repeated sequential operations that do not require more complex controllers.

Die 105 additionally includes a channel arbiter 315, a staging buffer 320, and a controller 325. HBM CA interface 300 receives command and address signals from an external host (not shown). Channel arbiter 315 arbitrates between left and right staging buffers 320 in service of those commands. If only one staging buffer is connected to a channel, the channel arbiter is not needed. The depicted staging buffer 320 buffers data going to and from accelerator tile ACC0, allowing rate matching so that read and write data bursts from and to accelerator die 105 can be matched to the regular, pipelined movement of data through the MAC arrays in the accelerator tiles.

A host controller (not shown) can change the operational mode of accelerator die 105 using a number of approaches, some of which are discussed below. Staging buffer 320 and control logic 325, one of which can be provided on the accelerator die for each external channel, monitor control switching status between the host controller and sequencers 310 to manage internal and external operational modes. Sequencers 310 can wait for a programmable period for control to be relinquished by the host controller. In one mode, an accelerator tile is provided direct access to an underlying stack of DRAM banks under control of a sequencer 310. In another mode, an accelerator tile is barred access to the underlying DRAM banks to allow conflict-free access to those underlying banks by a different component (e.g. by an alternative accelerator tile, control logic 325, or a controller external to the accelerator die). In another mode, an accelerator tile is provided direct access to a first portion of the underlying stack of DRAM banks under the control of sequencer 310, and is barred from access to a second portion of the underlying stack of DRAM banks to allow conflict-free external access to the second portion. The selected mode can be applied to any number of accelerator tiles, from one to all. In embodiments in which the memory dies are DRAM, maintenance operations (e.g. refresh and periodic calibration) can be managed by the active external or internal memory controller (e.g., the host or sequencer(s) 310). Each sequencer 310 can also monitor non-maintenance memory operations (e.g. whether a write and precharge sequence has been completed) so that control of the layer could be e.g. switched to another local or remote controller. The vertical-channel datapaths under control of sequencers 310 can have a different data rate than the HBM-channel datapath, e.g. by not utilizing bank grouping or by being multiplexed inside of the serializer/deserializer chain of the HBM-channel datapath.

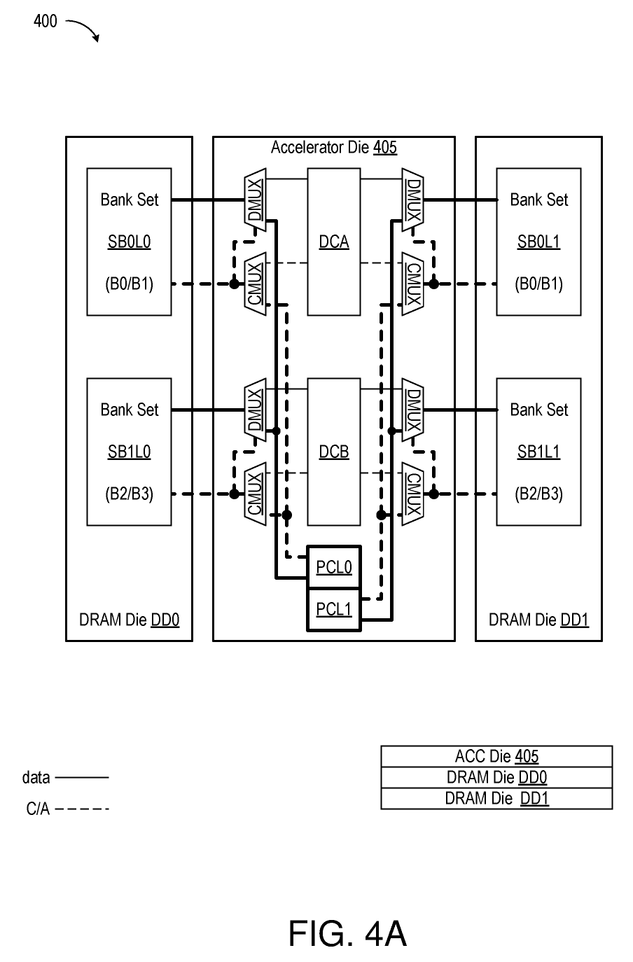

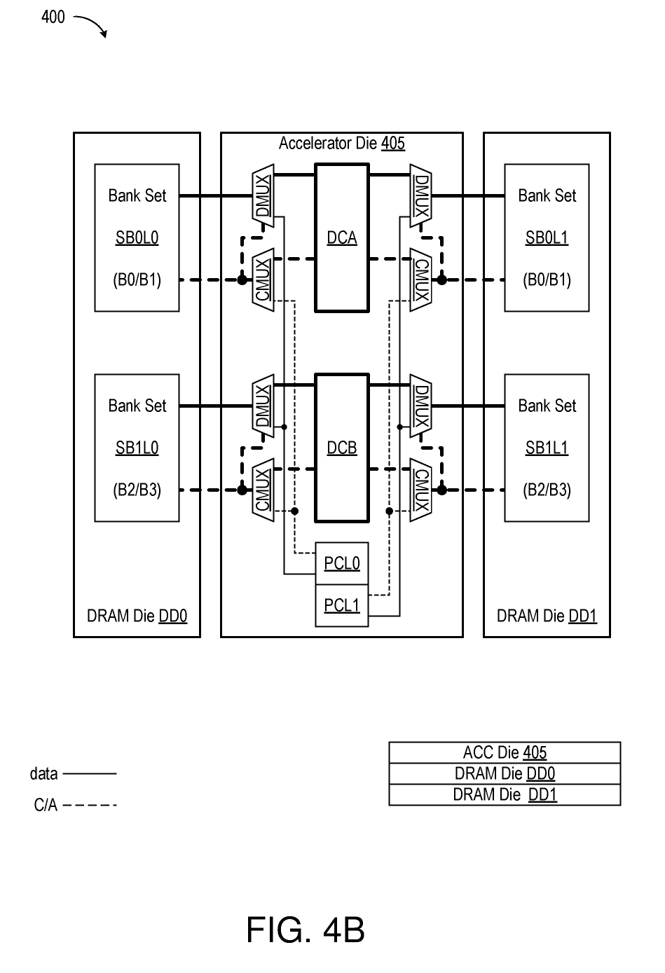

FIG. 4A is a block diagram of a 3-D ASIC 400 in accordance with an embodiment that includes an accelerator die 405 and a pair of DRAM dies DD0 and DD1. These dies are stacked as shown in cross-section at lower right but are depicted separately for ease of illustration.

Accelerator die 400 includes a number of functional blocks that represent aspects of die 105 of FIG. 1. A block DCA, for “direct-channel A,” affords accelerator die 405 access to a vertical, two-die stack of underlying sets of banks SB0L0 and SB0L1 in respective dies DD0 and DD1. A block DCB similarly affords direct access to underlying sets of banks SB1L0 and SB1L1. A block PCL0, for “pseudo-channel level 0,” affords accelerator die 400 access to both sets of banks SB0L0 and SB1L0 on die DD0, while a block PCL1 similarly affords access to both sets of banks SB0L1 and SB1L1 on die DD1. Collections of data multiplexers DMUX and command/address multiplexers CMUX on accelerator die 405 steer relevant signals.

The block diagram illustrates how data and command/address signals can be managed within accelerator die 405 to access underlying DRAM dies DD0 and DD1 in internal- and external-access modes like those detailed above. Solid lines extending between the various elements illustrate flows of data; dashed lines illustrate flows of command and address signals. Pseudo-channels PCL0 and PCL1 and related signal lines are highlighted using bold lines to illustrate signal flow in an external-access mode in which a host controller (not shown) accesses DRAM dies DD0 and DD1 via the pseudo channels. Blocks PCL0 and PCL1 provide access to sets of banks on respective DRAM dies DD0 and DD1.

FIG. 4B reproduces block diagram 400 of FIG. 4A but with direct-channel blocks DCA and DCB and related signal lines highlighted using bold lines to illustrate signal flow in an internal-access mode in which accelerator tiles (not shown) on accelerator die 405 access DRAM dies DD0 and DD1 directly via inter-die connections. Recalling that DRAM dies DD0 and DD1 are stacked vertically beneath accelerator die 405, block DCA provides access to a vertical stack of bank sets SB0L0/SB0L1 on DRAM dies DD0 and DD1 and block DCB provides access to a similar vertical stack of bank sets SB1L0/SB1L1.

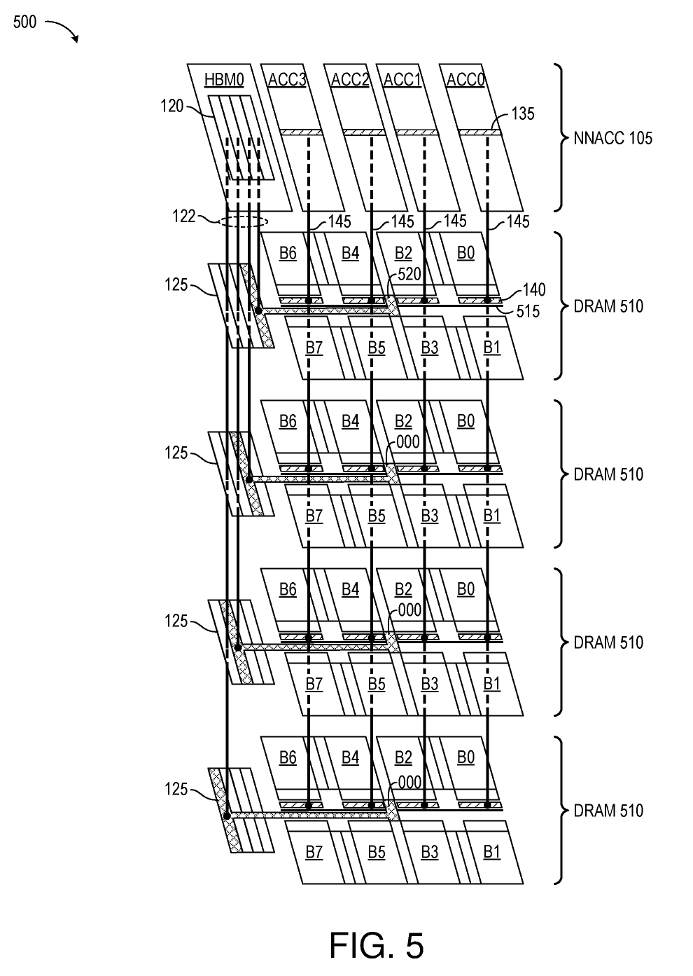

FIG. 5 depicts a 3-D ASIC 500 in accordance with another embodiment. ASIC 500 is similar to device 100 of FIG. 1, with like-identified elements being the same or similar. DRAM dies 510 are, in this embodiment, also modified to support relatively direct, inter-die connections to accelerator tiles ACC[3:0]. Bank grouping is implemented differently in this architecture with interleaving bursts from B[3:0] far from the HBM channel with bursts from B[7:4] near the HBM channel. The DRAM banks communicate data over a data channel 515 at a DRAM core frequency to bank-group logic 520 located in the middle of the set of banks. Data interleaved between two bank groups is communicated along a respective one of horizontal memory-die data ports 125 that is connected to bank-group logic 520. ASIC 500 otherwise operates in a manner similar to device 100 of FIGS. 1 and 2.

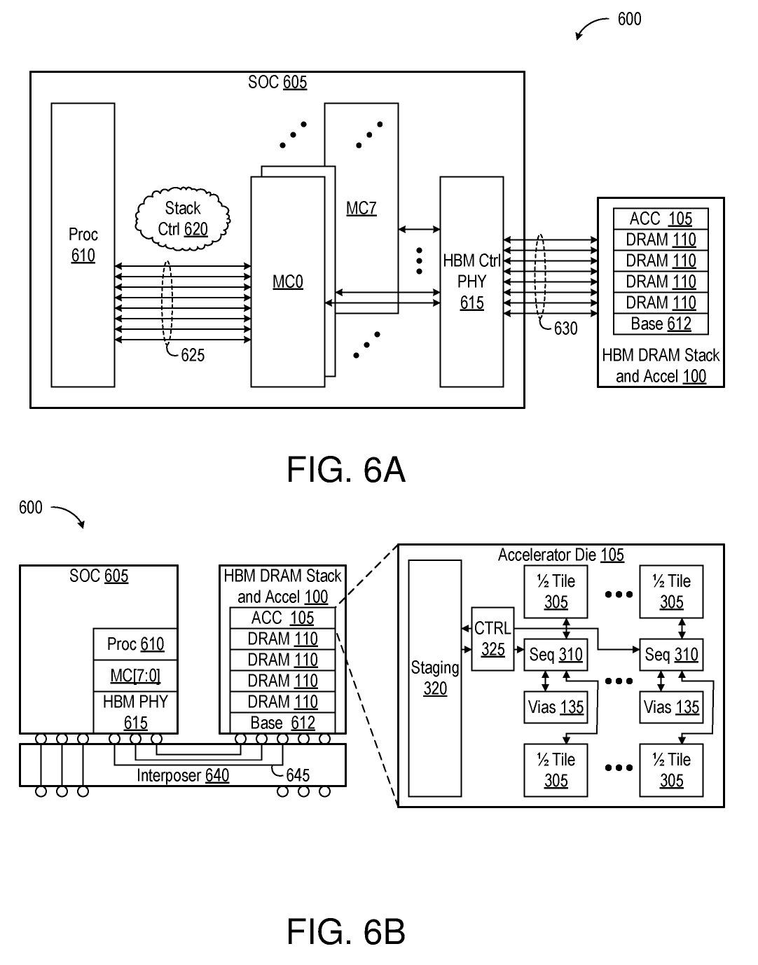

FIG. 6A depicts a computer system 600 in which a system-on-a-chip (SOC) 605 with host processor 610 has access to a 3-D processing device 100 of the type detailed previously. Though omitted from earlier figures, processing device 100 includes an optional base die 612 that can e.g. support test functions for the DRAM stack during manufacturing, distribute power, and change the stack’s ballout from the in-stack ballout to external microbumps. These and other functions can be incorporated on accelerator die 105, or the work of both accelerator and base dies 105 and 612 can be distributed differently between them.

Recalling from the discussion of FIG. 2 that device 100 supports eight HBM channels, processor 610 is provided with eight memory controllers MC[7:0], one for each HBM channel. Memory controllers MC[7:0] can be sequencers. SOC 605 also includes a physical layer (PHY) 615 to interface with device 100. SOC 605 additionally includes or supports, via hardware, software or firmware, stack-control logic 620 that manages mode selection for device 100 in a manner detailed below. Control switching time from SOC 605 to device 100 can vary across channels, with refresh and maintenance operations handled by sequencers 310 for channels in the internal-access mode. Global clock synchronization may not be necessary in accelerator die 105, though logic within the various tiles can be locally synchronous.

Processor 610 supports eight independent read/write channels 625, one for each external memory controller MC[7:0], that communicate data, address, control, and timing signals as needed. In this context, “external” is with reference to device 100 and is used to distinguish controllers (e.g. sequencers) that are integrated with (internal to) device 100. Memory controllers MC[7:0] and their respective portions of PHY 615 support eight HBM channels 630—two channels per DRAM die 110—communicating data, address, control, and timing signals that comply with HBM specifications relevant to HBM DRAM dies 110 in this example. In the external-access mode, device 100 interacts with SOC 605 in the manner expected of an HBM memory.

FIG. 6B depicts system 600 in an embodiment in which SOC 605 communicates with device 100 via an interposer 640 with finely spaced traces 645 etched in silicon. The HBM DRAM supports high data bandwidth with a wide interface. In one embodiment, HBM channels 630 include 1,024 data “wires” and hundreds more for command and address signals. Interposer 640 is employed because standard printed-circuit boards (PCBs) cannot manage the requisite connection density. Interposer 640 can be extended to include additional circuitry and can be mounted on some other form of substrate for interconnections to e.g. power-supply lines and additional instances of device 100.

A plan view of accelerator die 105, at right, depicts half tiles 305 and sequencers 310 that were introduced in the foregoing discussion of FIG. 3. The external mode might be called the “HBM mode” in this example, as device 100 performs as a conventional HBM memory in that mode. Processor 610 may employ the HBM mode to load the DRAM stack with training data. Processor 610 can then issue instructions to device 100 that direct accelerator die 105 to enter the accelerator mode and execute a learning algorithm that settles on a function or functions optimized to achieve a desired result. This learning algorithm employs sequencers 310, controller 325, and the inter-die connections afforded by via fields 135 to access the training data and neural network model parameters in underlying DRAM banks and to store intermediate and final outputs. Accelerator die 105 also uses sequencers 310 to store in DRAM neural-network parameters settled upon during optimization. The learning algorithm can proceed with little or no interference from SOC 605, which can similarly direct a number of neural networks in tandem. Processor 610 can periodically read an error register (not shown) on device 100 to monitor the progress of the learning algorithm. When the error or errors reaches a desired level, or fails to reduce further with time, processor 610 can issue an instruction to device 100 to return to the HBM mode and read out the optimized neural-network parameters—sometimes called a “machine-learning model”—and other data of interest.

In some embodiments device 100 is only in one mode or the other. Other embodiments support more granular modality, allowing different banks to be directed by different external and internal memory controllers while avoiding bank conflicts. In the example of FIGS. 6A and 6B, stack control logic 620 manages the access mode for each of the eight channels 625, and thus for the HBM channels 630 to device 100. With reference to the embodiment of FIG. 2, for example, the four external channels associated with interface HBM0 can be in the HBM mode, allowing the host processor access to the sixteen sets of banks (four banks per DRAM die) underlying the accelerator die; while the four external channels associated with interface HBM1 are disabled in favor of direct bank access by the accelerator tiles (not shown) above the other sixteen sets of banks.

Processor 610 can change the operational mode of device 100 using a number of approaches. These include issuing instructions to load per-channel or per-tile (accelerator tile) registers that control the sequencers 310 associated with the affected tile or tiles. Aperture-style access may also be used, in which case the accelerator tiles could be mapped to virtual address space outside of the addresses of the DRAM banks. Additional pins, traces, and address fields can accommodate the additional addresses. In some embodiments, system 600 includes global mode registers accessed through an IEEE 1500 sideband channel that allows address space ownership to transfer between external host processor 610 (e.g. per channel 625) to sequencers 310 within accelerator die 105. Neural-network training and inference operations are deterministic so that mode selection dividing the DRAM address space for external and internal access can be set by a compiler before system 600 is tasked with machine learning on a set of training data. Such control switching can be relatively infrequent and so have little impact on performance.

In one embodiment, each DRAM die 110 issues a “ready” signal indicating when the die is not in use. External memory controllers MC[7:0] use this status information to determine when a DRAM die 110 is not in use by accelerator die 105 and is thus available for external access. Memory controllers MC[7:0] take control of e.g. refresh operations for DRAM banks or dies that are not under the control of an internal controller. Accelerator die 105 can hand control back to the host processor on a per-channel basis, “per-channel” referring to one of the eight external channels from external controllers MC[7:0]. In one embodiment, each sequencer 310 monitors the per-layer ready signals from the underlying DRAM dies for control switching. Control switching for each DRAM die can take place at different times. In one embodiment, to relinquish control of memory banks associated with a given external channel, controller 325 on accelerator die 105 issues the ready signal via that channel to the corresponding host memory controller MC#. Processor 610 then takes back control using e.g. one of the aforementioned approaches for communicating with relevant sequencers 310. During the switching process, staging and control logic 320/325 monitor control switching status and communicates to all tile sequencers 310. The host memory controller MC# can wait for programmable period for control to be relinquished by all sequencers 310. Refresh and maintenance operations are handled by the host memory controller MC# after switching.

The ready signal issued by controller 325 can be an asynchronous, pulse-width modulated (PWM) global signal that indicates successful completion of e.g. some neural-network learning process (e.g., an error is reduced to a specified level, the error settles on a relatively stable value, or the training data is exhausted). Internal error status (instead of successful completion) can be communicated using different pulse widths. SOC 605 can implement a timeout followed by status-register read and error recovery to handle unforeseen errors for which the ready signal is not asserted. SOC 605 can also read status registers, for e.g. training errors, periodically. Status registers can be integrated into accelerator tile 105 on a per-tile basis and/or as a combined status register for the accelerator tile.

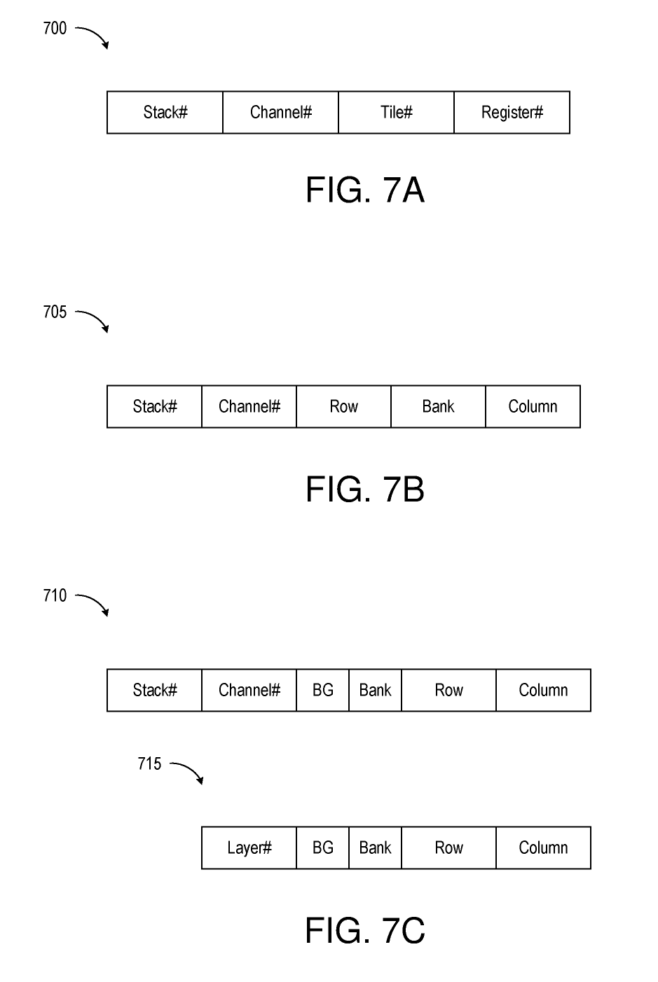

FIG. 7A depicts an address field 700 that can be issued by a host processor to load a register in accelerator die 105 to control the mode. A “Stack#” field identifies device 100 as one of a group of similar devices; a “Channel#” field identifies the channel and pseudo channel through which the register is accessed; the “Tile#” field identifies the target accelerator tile or tiles; and the register field “Register#” identifies the address of the register or registers that control the operational mode of the target tile or tiles. A one-bit register controlling a given tile, for example, might be loaded with a logic one or zero to set corresponding sequencer 310 (FIG. 3) to an external- or internal-access mode, respectively.

FIG. 7B depicts an address field 705 that can be used by a host processor for aperture-style mode selection. The Stack# and Channel# field are as described previously. The Row, Bank, and Column fields express bits normally associated with DRAM address space but are, for mode selection, set to values outside of that space. Accelerator die 105 includes registers that can be selected responsive to these addresses.

Returning to FIGS. 6A and 6B, external memory controllers MC[7:0] independently access eight memory channels, two HBM channels 630 for each of four DRAM dies 110. Each HBM channel, in turn, provides access to four bank groups on the same DRAM die 110, each bank group having eight banks, or thirty-two banks in total. Each sequencer 310, on the other hand, provides access to two banks on each of four DRAM dies 110, or eight banks in total. Address mapping can therefore be different for the external- and internal access modes.

FIG. 7C depicts two address fields, an external-mode address field 710 that can be issued by a host processor to access a page of DRAM in the HBM mode and an internal-mode address field 715 that can be used by an internal memory controller for similar access. In the external address mapping scheme, address field 710 specifies a stack and channel, as noted previously, and additionally a bank group BG, bank, row, and column to access a DRAM page. The internal address mapping scheme is different from the external address mapping scheme. Address field 710 omits the stack, there being only one, and includes a field Layer# to select from among the four layers in the underlying vertical stack of available DRAM banks. Larger vertical channels can be split across multiple layers, e.g. two of four in this four DRAM example.

Internal-mode address field 715 allows an internal controller to select any column in the underlying DRAM dies. Address field 715 can have fewer bits in embodiments in which each accelerator tile has access to a subset of the banks available on the same device 100. With reference to FIG. 1, in one embodiment each accelerator tile ACC# only has access to the stack of memory banks directly beneath (e.g., tile ACC0 only has access to the stack of memory banks B0 and B4 in the four DRAM dies 110). Bank-group and bank fields BG and Bank can thus be simplified to a single bank bit that distinguishes banks B0 and B4 in the specified layer.

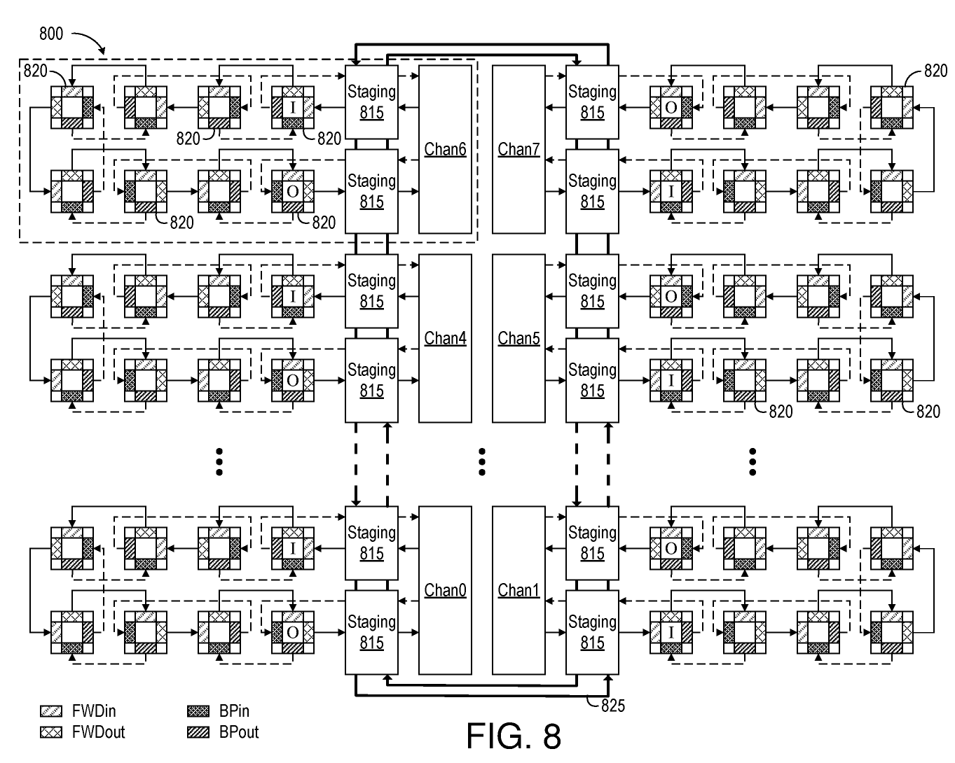

FIG. 8 illustrates an application-specific integrated circuit (ASIC) 800 for an artificial neural network with an architecture that minimizes connection distances between processing elements and memory (e.g. stacked memory dies), and thus improves efficiency and performance. ASIC 800 additionally supports minibatching and pipelined, concurrent forward and back propagation for training. Minibatching splits training data into small “batches” (minibatches), while pipelined and concurrent forward and back propagation support fast and efficient training by simultaneously propagating forward training samples while concurrently backpropagating the adjustments from previous training samples.

ASIC 800 communicates externally using eight channel interfaces Chan[7:0], which can be HBM channels of the typed discussed previously. A pair of staging buffers 815 next to each channel interface buffers data going to and from the memory core (not shown). Buffers 815 allow rate matching so that read and write data bursts from and to tiles 820 through the eight channel interfaces Chan[7:0] can be matched to regular, pipeline movement of an array of accelerator tiles 820. Processing elements within a tile can operate as a systolic array, as detailed below, in which case tiles can be “chained” together to form larger systolic arrays. Buffers 815 can be interconnected via one or more ring busses 825 for increased flexibility, for example to allow data from any channel to be sent to any tile, and to support use cases in which network parameters (e.g. weights and biases) are partitioned so that processing happens on portions of the neural network. Ring busses that convey signals in opposite directions can improve fault tolerance and performance.

ASIC 800 is divided into eight channels, each of which can be used for minibatching. One channel comprises one channel interface Chan#, a pair of staging buffers 815, a series of accelerator tiles 820, and supporting memory (not shown). The channels are functionally similar. The following discussion is limited to the upper-left channel Chan6, which is bounded by a dashed border. The accelerator tile 820 labeled “I” (for “input”) receives input from one of buffers 815. This input tile 820 is upstream from the next tile 820 to the left. For inference, or “forward propagation,” information moves along the unbroken arrows through the chain of tiles 820, emerging from the ultimate downstream tile labeled “O” (for “output”) to another of staging buffers 815. For training, or “back propagation,” information moves along the broken arrows from the ultimate downstream tile labeled “O,” emerging from the ultimate upstream tile labeled “I.”

Each tile 820 includes four ports, two each for forward propagation and back propagation. A key at the lower left of FIG. 8 shows shading that identifies in each tile 820 a forward-propagation input port (FWDin), forward-propagation output port (FWDout), back-propagation input port (BPin), and back-propagation output port (BPout). Tiles 820 are oriented to minimize connection distances in an embodiment in which tiles 820 can occupy different layers of a 3D-IC. As detailed below, each tile 820 includes an array of processing elements, each of which can concurrently process and update partial results from both upstream and downstream processing elements and tiles in support of concurrent forward and back propagation. In this embodiment, each tile 820 overlaps a vertical stack of individual memory banks. Accelerator tiles can, however, be sized to overlap stacks of bank pairs, as in the example of FIG. 1, or stacks of other numbers of banks (e.g., four or eight banks per die). In general, each memory occupies a bank area and one accelerator tile occupies a tile area substantially equal to the area of a whole number of the bank areas.

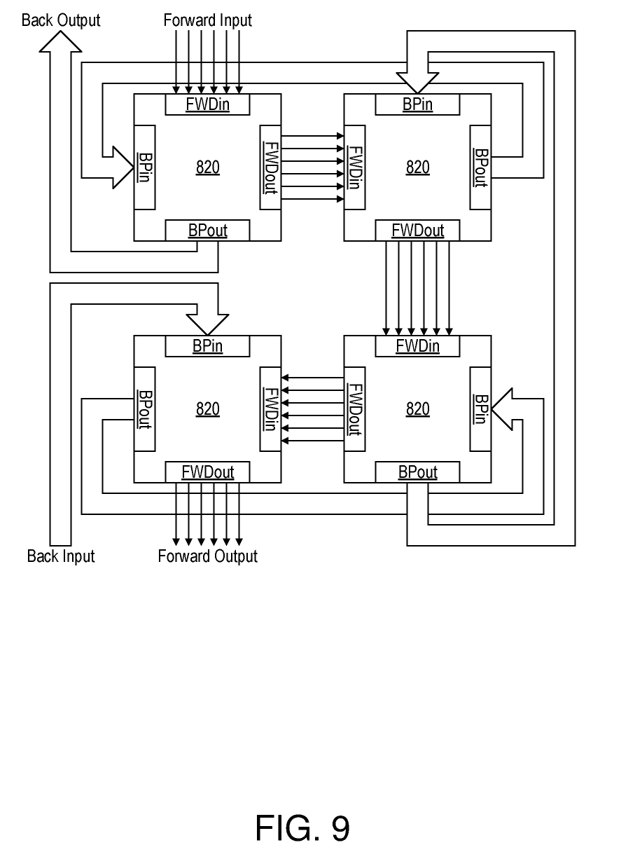

FIG. 9 illustrates four accelerator tiles 820 interconnected to support concurrent forward and back propagation. Thin, parallel sets of arrows represent the path of forward propagation through these four tiles 820. Solid arrows represent the path of back propagation. Forward- and back-propagation ports FWDin, FWDout, BPin, and BPout are unidirectional in this example, and both forward- and back-propagation sets of ports can be used concurrently. Forward propagation traverses tiles 820 in a clockwise direction beginning with the upper left tile. Back propagation proceeds counterclockwise from the lower left.

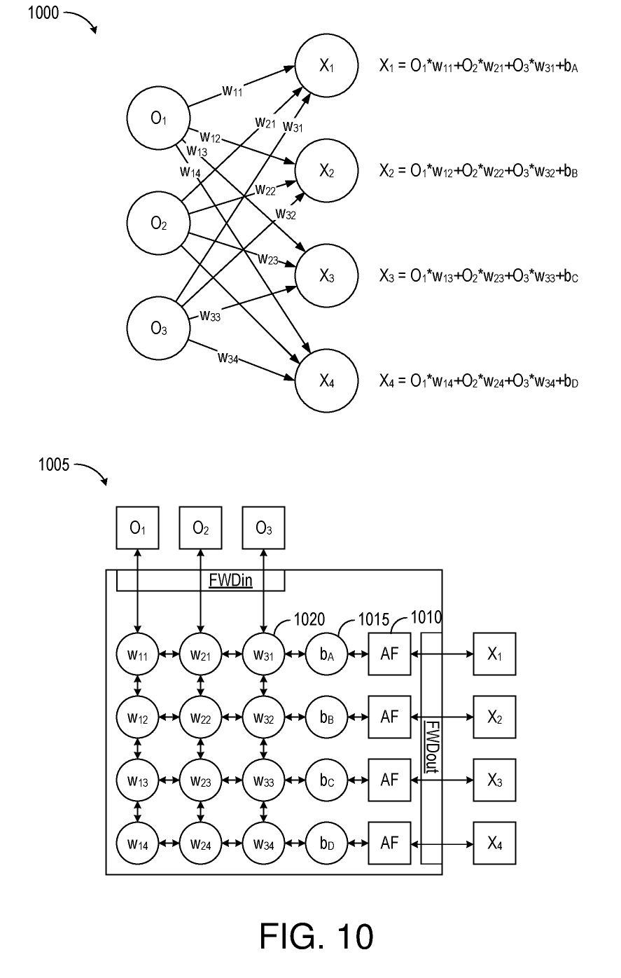

FIG. 10 includes a functional representation 1000 and an array 1005 of a neural network instantiated on a single accelerator tile 820. Representation 1000 and array 1005 illustrate forward propagation and omit back-propagation ports BPin and BPout for ease of illustration. Back propagation is detailed separately below.

Functional representation 1000 is typical of neural networks. Data comes in from the left represented by a layer of neurons O₁, O₂, and O₃, each of which receives a respective partial result from one or more upstream neurons. Data leaves from the right represented by another layer of neurons X₁, X₂, X₃ and X₄ that convey their own partial results. The neurons are connected by weighted connections wᵢⱼ, sometimes called synapses, the weightings of which are determined in training. The subscript of each weighting references the origin and destination of the connection. The neural network calculates a sum of products for each output neuron following the equations shown in FIG. 10. A bias term b# references a bias neuron that is omitted here for ease of illustration. Bias neurons and their use are well known so a detailed discussion is omitted.

Array 1005 of an accelerator tile 820 is a systolic array of processing elements 1010, 1015, and 1020. In a systolic array, data is transmitted in a stepwise fashion from one processing element to the next. For each step, each processing element computes a partial result as a function of the data received from an upstream element, stores the partial result in anticipation of the next step, and passes the result to a downstream element.

Elements 1015 and 1020 perform the calculations associated with forward propagation per functional representation 1000. In addition, each of elements 1010 performs an activation function that transforms the output of that node in ways that are well understood and unnecessary for the present disclosure. The layers, represented as neurons in representation 1000, are depicted in array 1005 as data inputs and outputs, with all computation performed by processing elements 1010, 1015, and 1020. Processing elements 1015 include simple accumulators that add a bias to a value that is accumulating, whereas elements 1020 include MACs, each of which computes the product of two numbers and adds that product to an accumulating value. Each processing element 1020 can include more than one MAC, or compute elements that are different than MACs in other embodiments. Processing elements 1010, 1015, and 1020 support pipelined and concurrent forward and back propagation, as detailed below, to minimize idle time and thus increase hardware efficiency.

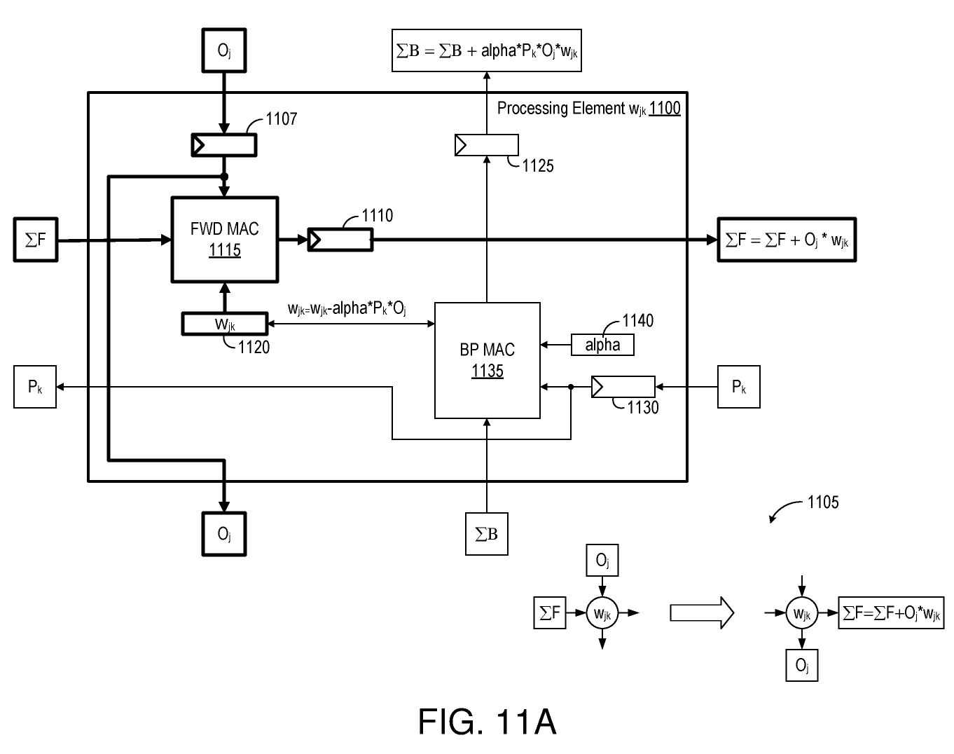

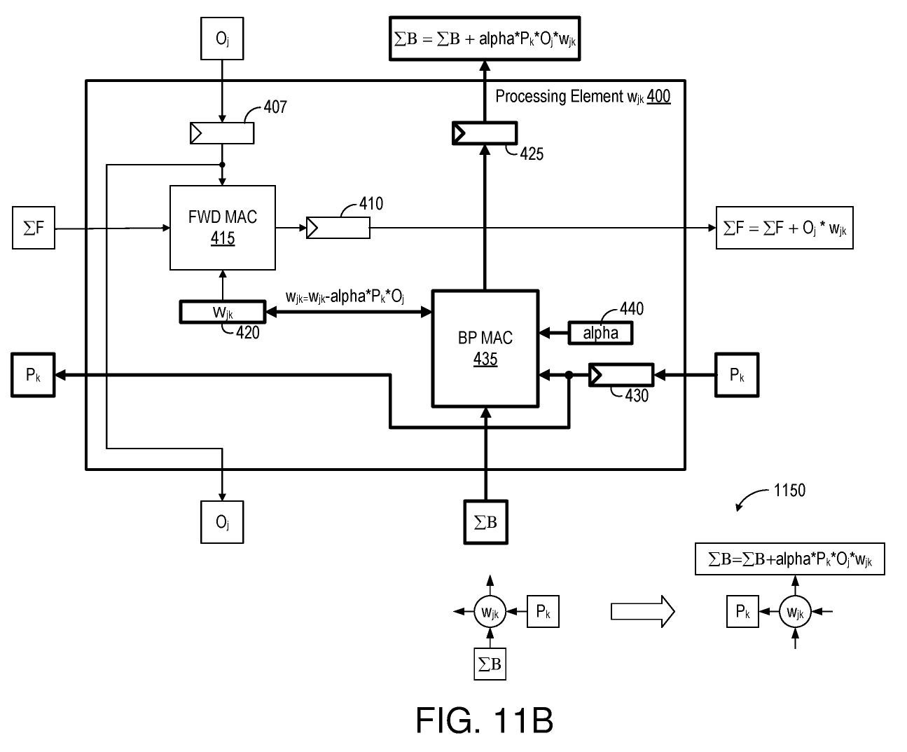

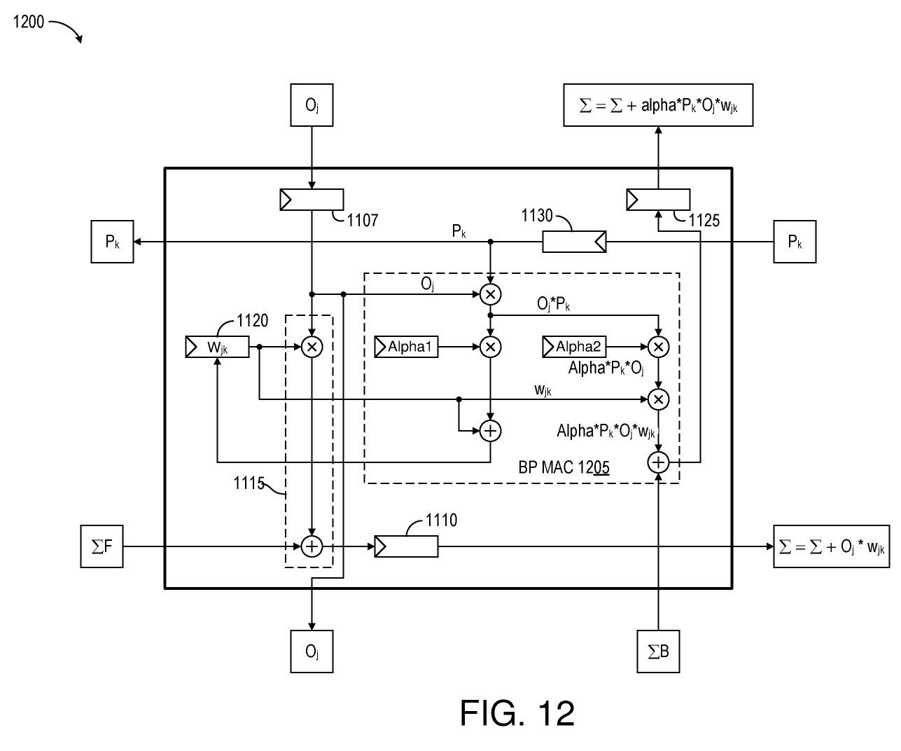

FIG. 11A depicts a processing element 1100, an example of circuitry suitable for use as each processing element 1020 of FIG. 10. Element 1100 supports concurrent forward and back propagation. Circuit elements provided in support of forward propagation are highlighted using bold line widths. A diagram 1105 at the lower right provides a functional description of element 1100 transitioning between states of forward propagation. To start, element 1100 receives as inputs a partial sum Oⱼ from an upstream tile and a forward-propagation partial result EF, if any, from an upstream processing element. After one compute cycle, processing element 1100 produces an updated partial result ΣF=ΣF+Oⱼ*wⱼₖ and passes partial sum Oⱼ to another processing element 1100. With reference to array 1005 of FIG. 10, for example, the processing element 1020 labeled W₂₂ passes a partial sum to the downstream element labeled W₃₂ and relays output O₂ to the element labelled w₂₃.

Returning to FIG. 11A, processing element 1100 includes, as support for forward propagation, a pair of synchronous storage elements 1107 and 1110, a forward-propagation processor 1115, and local or remote storage 1120 to store a weighting value, or weight wⱼₖ, for calculating partial sums. Processor 1115, a MAC, calculates the forward partial sum and stores the result in storage element 1110. In support of back propagation, processing element 1100 includes another pair of synchronous storage elements 1125 and 1130, a back-propagation MAC 1135, and local or remote storage 1140 to store a value alpha that is used during training to update weight wⱼₖ.

FIG. 11B depicts processing element 1100 of FIG. 11A with circuit elements provided in support of back propagation highlighted using bold line widths. A diagram 1150 at the lower right provides a functional description of element 1100 transitioning between states of back propagation. Element 1100 receives as inputs a partial sum Pₖ from a downstream tile and a back-propagation partial result EB, if any, from a downstream processing element. After one compute cycle, processing element 1100 produces an updated partial result ΣB=ΣB+alpha*Pₖ*Oⱼ*wⱼₖ to an upstream processing element 1100. Alpha specifies a learning rate by controlling how much to change the weight in response to estimated errors.

FIG. 12 depicts a processing element 1200 similar to processing element 1100 of FIGS. 11A and 11B, with like-identified elements being the same or similar. A MAC 1205 in service of back propagation includes four multipliers and two adders. MAC 1205 stores two learning-rate values Alpha1 and Alpha2, which can adjust back-propagation calculations differently. For each calculation, one might want to add a scale factor to emphasize or de-emphasize how much the calculation affects an old value. Processing elements can have more or fewer multipliers and adders in other embodiments. For example, processing element 1200 can be simplified by reusing hardware (e.g., multipliers or adders), though such modification may reduce processing speed.

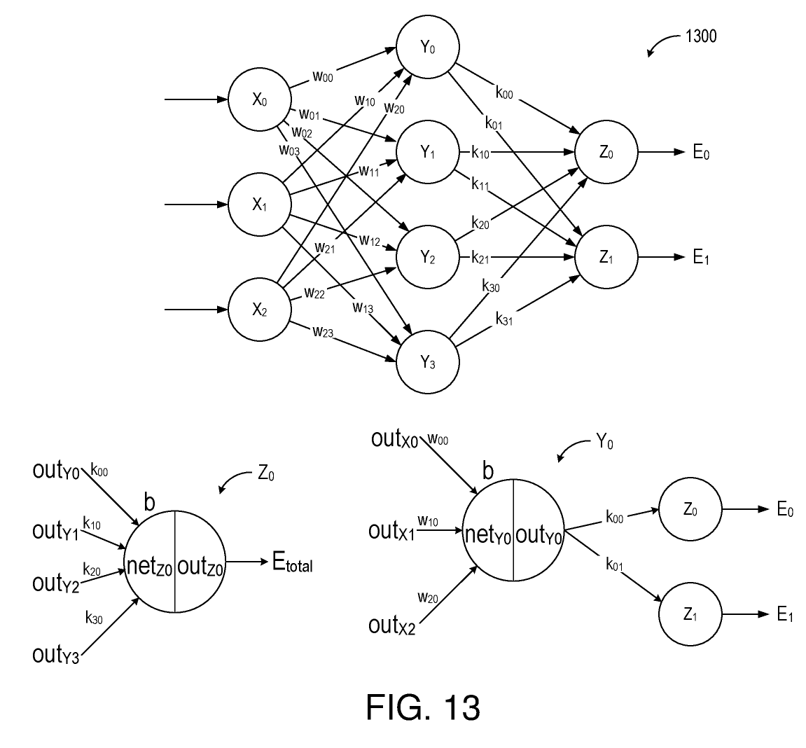

FIG. 13 illustrates information flow during back propagation through accelerator tile 1200 of FIG. 12. For back propagation, the calculations performed at the last layer of the neural network are different than for all other layers. Equations can vary by implementation. The following examples illustrate the hardware used for layers other than the output layer because they require more computation.

A simple neural network 1300 representation includes an input layer X[2:0], a hidden layer Y[3:0], and an output layer Z[1:0] producing errors E[1:0]. Neuron Z₀ of the output layer-neurons are also called “nodes”—is shown divided into net_{Z0} and out_{Z0} at lower left. Neuron Y₀ of the hidden layer is shown divided into net_{Y0} and out_{Y0} at lower right. Each neuron is provided with a respective bias b. This graphical representation, for ease of illustration, represents a systolic array of processing elements (e.g. elements 1020 of FIG. 10 and elements 1100 and 1200 of FIGS. 11 and 12) that support concurrent forward and back propagation as detailed herein.

Output-layer calculations for back propagation use the total error from the previous step. Stated mathematically for N outputs outₒ:

$${E}_{t o t a l} = \frac{1}{2} {\left(D e s i r e {d}_{o 0} - o u {t}_{o 0}\right)}^{2} + ⋯ \frac{1}{2} {\left(D e s i r e {d}_{o N - 1} - o u {t}_{o N - 1}\right)}^{2}$$

In network 1300 N=2. The gradient for each weight is calculated for each weight based on its contribution to total error Eₜₒₜₐₗ.

For each output node O {

For each incoming weight/bias connected to output node O {

Use the chain rule to determine the error contribution of the weight/bias and adjust it. This illustration assumes e.g. a Sigmoid activation function, the derivative of which is equation 4 below. Considering total error Eₜₒₜₐₗ from output node Z₀:

$$\frac{\partial {Ε}_{t o t a l}}{\partial {k}_{00}} = \frac{\partial {Ε}_{t o t a l}}{\partial o u {t}_{Z 0}} ∗ \frac{\partial o u {t}_{Z 0}}{\partial n e {t}_{Z 0}} ∗ \frac{\partial n e {t}_{Z 0}}{\partial {k}_{00}}$$

$$\frac{\partial {Ε}_{t o t a l}}{\partial o u {t}_{Z 0}} = o u {t}_{Z 0} - D e s i r e {d}_{Z 0}$$

$$\frac{\partial o u {t}_{Z 0}}{\partial n e {t}_{Z 0}} = o u {t}_{Z 0} ∗ \left(1 - o u {t}_{Z 0}\right)$$

$$\frac{\partial n e {t}_{Z 0}}{\partial {k}_{00}} = o u {t}_{Y 0}$$

$${k}_{00} = {k}_{00} - α * \frac{\partial {Ε}_{t o t a l}}{\partial {k}_{00}}$$

} }

Hidden-layer calculations for back propagation are also based on the total error but the equations are different. One embodiment, for example, works as follows: For each hidden node Y {

Use the chain rule to determine the error contribution of the weight and adjust it:

$$\frac{\partial {Ε}_{t o t a l}}{\partial {w}_{00}} = {\sum }_{0} \left(\frac{\partial {Ε}_{t o t a l}}{\partial o u {t}_{Z 0}} ∗ \frac{\partial o u {t}_{Z 0}}{\partial n e {t}_{Z 0}} ∗ \frac{\partial n e {t}_{Z 0}}{\partial {Y}_{0}}\right) ∗ \frac{\partial o u {t}_{Y 0}}{\partial n e {t}_{Y 0}} ∗ \frac{\partial n e {t}_{Y 0}}{\partial {w}_{00}}$$

$$\frac{\partial {Ε}_{t o t a l}}{\partial {w}_{00}} = \frac{\partial {Ε}_{t o t a l}}{\partial o u {t}_{Y 0}} ∗ \frac{\partial o u {t}_{Y 0}}{\partial n e {t}_{Y 0}} ∗ \frac{\partial n e {t}_{Y 0}}{\partial {w}_{00}}$$

$$\frac{\partial {Ε}_{t o t a l}}{\partial o u {t}_{Y 0}} = \frac{\partial {Ε}_{0}}{\partial o u {t}_{Y 0}} + \frac{\partial {Ε}_{1}}{\partial o u {t}_{Y 0}}$$

$$\frac{\partial o u {t}_{Y 0}}{\partial n e {t}_{Y 0}} = o u {t}_{Y 0} ∗ \left(1 - o u {t}_{Y 0}\right)$$

$$\frac{\partial n e {t}_{Y 0}}{\partial {w}_{00}} = o u {t}_{X 0}$$

$${w}_{00} = {w}_{00} - α ∗ \frac{\partial {Ε}_{t o t a l}}{\partial {w}_{00}}$$

} }

If a neural network has multiple hidden layers, error term Eₜₒₜₐₗ is the error at the next layer of nodes, which can be calculated by the difference between the actual and desired outputs of the nodes. The desired output is calculated in the previous iteration when the next layer was adjusted.

Back propagation works from the outputs to the inputs, so the previous layer’s adjustments are known when the current layer’s adjustments are being calculated. The process can be conceptualized as a sliding window over three layers of nodes, where one looks at the errors of the rightmost layer and uses them to compute adjustments to weights coming into the middle layer of the window.

While the foregoing discussion contemplates the integration of neural-network accelerator die with DRAM memory, other types of tightly integrated processors and memory can benefit from the above-described combinations of modes and channels. For example, additional stacked accelerator dies can be included with more or fewer DRAM dies, the accelerator die or a subset of the accelerator tiles can be replaced with or supplemented by one or more graphics-processing die or tiles, and the DRAM die or dies can be replaced or supplemented with different types of dynamic or non-volatile memory. Variations of these embodiments will be apparent to those of ordinary skill in the art upon reviewing this disclosure. Moreover, some components are shown directly connected to one another while others are shown connected via intermediate components. In each instance the method of interconnection, or “coupling,” establishes some desired electrical communication between two or more circuit nodes, or terminals. Such coupling may often be accomplished using a number of circuit configurations, as will be understood by those of skill in the art. Therefore, the spirit and scope of the appended claims should not be limited to the foregoing description. Only those claims specifically reciting “means for” or “step for” should be construed in the manner required under the sixth paragraph of 35 U.S.C. §112.

What is claimed is:

1. An integrated circuit (IC) device comprising:
a processor die having at least one processing tile;
memory dies stacked with and bonded to the processor die, each memory die defining a memory-die plane and having:
memory banks spaced in the memory-die plane by a memory-bank pitch;
an inter-die data port connected to at least one of the memory banks on the memory die; and
an intra-die data port connected to the memory banks on the memory die; and
an inter-die data connection extended from the processing tile of the processor die to the inter-die data ports of the memory dies.

2. The device of claim 1, the processor die further including a memory interface divided into sub-interfaces, each sub-interface connected to the intra-die data port of a respective one of the memory dies.

3. The device of claim 1, wherein at least one of the inter-die data ports and the intra-die data ports comprises a via field.

4. The device of claim 1, the processor die further having a first via field electrically connected to the intra-die data port of a first of the memory dies and electrically isolated from the intra-die data port of a second of the memory dies.

5. The device of claim 4, the processor die further having a second via field electrically connected to the intra-die data port of the second of the memory dies and electrically isolated from the intra-die data port of the first of the memory dies.

6. The device of claim 1, further comprising a base die bonded to the processor die and the memory dies and communicatively coupled to the intra-die data ports.

7. The device of claim 1, wherein each of the memory banks occupies a bank area and one tile of the at least one processing tile occupies a tile area substantially equal to the area of a whole number of the bank areas.

8. The device of claim 7, wherein the one tile has a tile boundary encompassing the area of the whole number of the bank areas from a perspective normal to the processor die.

9. The device of claim 1, the processor die further having a controller to manage communication between the processing tile and inter-die data ports of the memory dies.

10. The device of claim 1, each memory die having a second inter-die data port connected to one of the memory banks different from the at least one of the memory banks to which the first-mentioned inter-die data port is connected.

11. The device of claim 10, wherein the intra-die data port on each of the memory dies is connected to the ones of the memory banks to which the first-mentioned and second inter-die data ports are connected.

12. The device of claim 1, the processor die including an array of interconnected processing elements, including upstream processing elements and downstream processing elements, each processing element including:
a forward-propagation input port to receive a forward partial result;
a forward-propagation processor to update the forward partial result;
a forward-propagation output port to transmit the updated forward partial result;
a back-propagation input port to receive a back-propagation partial result;
a back-propagation processor to update the back-propagation partial result; and
a back-propagation output port to transmit the updated back-propagation partial result.

13. The device of claim 12, wherein the forward-propagation processor and the back-propagation processor concurrently update the forward partial result and the back-propagation partial result, respectively.

14. An integrated circuit (IC) processing device comprising:
stacked first and second memory dies each having a first memory bank of a first memory-bank area and a second memory bank of a second memory-bank area, wherein the first and second memory-bank areas of the first memory die overlay the first and second memory-bank areas of the second memory die from a perspective normal to the memory dies; and
a neural-network accelerator die disposed over the first and second memory dies, the accelerator die including:
a first neural-network accelerator tile;
a first memory controller vertically coupled, via first inter-die connections, to the first memory bank of the first memory die and to the first memory bank of the second memory die, the first memory controller to manage data communication between the first neural-network accelerator tile and the first memory bank of the first memory die and the first memory bank of the second memory die;
a second neural-network accelerator tile; and
a second memory controller vertically coupled, via second inter-die connections, to the second memory bank of the first memory die and to the second memory bank of the second memory die, the second memory controller to manage data communication between the second neural-network accelerator tile and the second memory bank of the first memory die and the second memory bank of the second memory die.

15. The device of claim 14, further comprising a memory interface to receive commands from a host controller external to the processing device, the memory interface to issue the commands from the host controller to the first memory controller and the second memory controller.

16. The device of claim 15, further comprising at least one mode register coupled to the first memory controller and the second memory controller, the at least one mode register to store a mode value, responsive to one of the commands from the host controller, to enable at least one of the first memory controller and the second memory controller.

17. The device of claim 15, wherein the commands from the host controller specify addresses in the first and second memory banks using an external address-mapping scheme and the first memory controller specifies the addresses in the first memory banks of the first and second memory dies using an internal address-mapping scheme different from the external address-mapping scheme.

18. The device of claim 17, wherein the first memory banks constitute a first stack of the memory banks, the second memory banks constitute a second stack of the memory banks, the external address-mapping scheme distinguishes the first stack from the second stack, and the internal address mapping scheme does not distinguish the first stack from the second stack.

19. The device of claim 14, wherein the first memory controller performs accesses and maintenance operations on the first memory banks and the second memory controller performs accesses and maintenance operations on the second memory banks.

20. The device of claim 19, further comprising a memory interface to receive commands from a host controller external to the processing device, the memory interface to issue the commands to enable and disable the first and second memory controllers.

21. The device of claim 20, wherein the host controller performs the maintenance operations on the first and second memory banks while the first and second memory controllers are disabled.

22. The device of claim 14, wherein at least one of the first and second memory controllers comprises a sequencer.
